(19) United States
(12) Patent Application Publication
(10) Pub. No.: US 2019/0103420 A1
(43) Pub. Date: Apr. 4, 2019

(54) ARRAY SUBSTRATE, DISPLAY DEVICE, AND MANUFACTURING METHOD THEREOF

(71) Applicant: Shenzhen China Star Optoelectronics Technology Co. Ltd., Shenzhen, Guangdongcn (CN)

(72) Inventors: Zhaosong LIU, Shenzhen, Guangdong (CN); YUAN-JUN HSU, Shenzhen, Guangdong (CN); Songshan LI, Shenzhen, Guangdong (CN)

(73) Assignee: Shenzhen China Star Optoelectronics Technology Co. Ltd., Shenzhen, Guangdong (CN)

(21) Appl. No.: 15/536,924

(22) PCT Filed: May 27, 2017
(86) PCT No.: PCT/CN2017/086232

§ 371 Date: Jun. 16, 2017

(30) Foreign Application Priority Data
Apr. 28, 2017 (CN) 201710294119.8

(51) Int. Cl. H01L 27/12

(52) U.S. Cl. CPC H01L 27/1225; H01L 27/1218; H01L 27/1237; H01L 27/127; H01L 27/1262

(57) ABSTRACT

This invention discloses an array substrate, a display device and a manufacturing method thereof. The array substrate includes a base substrate and a low temperature polysilicon transistor and an oxide transistor positioned on the base substrate; the low temperature polysilicon transistor includes a laminated polysilicon layer and a first insulating layer, the first insulating layer comprising a silicon oxide layer and silicon nitride layer, wherein the silicon nitride layer is positioned between the polysilicon layer and the silicon oxide layer; the oxide transistor includes a laminated oxide semiconductor layer and a second insulating layer, and the second insulating layer is free of a silicon nitride layer. By the method, the leakage problem of the low temperature polysilicon transistor is effectively reduced, and the reliability of the oxide transistor is improved.

### TECHNICAL FIELD

This invention relates to a planar display technology, in particularly to an array substrate, a display device, and a manufacturing method thereof.

### BACKGROUND OF RELATED ART

Flat display devices have the advantages of thin body, power saving, no radiation and the like, and have been widely used. The current flat display devices mainly include liquid crystal display (LCD) and organic light emitting diode (OLED), and active matrix organic light emitting diode (AMOLED) has a significant advantage over LCD in terms of energy consumption, color saturation, contrast, and flexible applications.

In the long-term research and development, the inventors of this application have found that thin film transistors (TFTs) are required to have high fluidity due to the electric current driven of AMOLED panels. In the prior art, low temperature polysilicon (LTPS) technology is combined with the oxide thin film transistor (Oxide TFT), which are manufactured in the same device. However, if the ILD film is improperly selected during the manufacturing process, the polysilicon can not be sufficiently repaired during the hydrogenation process, resulting in the consequences of leakage, or the problem of reduced reliability caused by excessive hydrogen atoms penetrating the oxide semiconductor layer.

### SUMMARY

The technical problem that this invention mainly solves is to provide an array substrate, a display device and a manufacturing method thereof; by the method, the leakage problem of the low temperature polysilicon transistor is effectively reduced, and the reliability of the oxide transistor is improved.

To solve the technical problems, a technical proposal of this invention is to provide a display device, including the array substrate, the array substrate includes a base substrate and a low temperature polysilicon transistor and an oxide transistor positioned on the base substrate, the base substrate is provided with a display region and a non-display region located around the display region, the low temperature polysilicon transistor is positioned in a non-display region, and the oxide transistor is positioned in a display region; the low temperature polysilicon transistor includes a laminated polysilicon layer, a first insulating layer and a third insulating layer, the first insulating layer including a silicon oxide layer and a silicon nitride layer, wherein the silicon nitride layer is positioned between the polysilicon layer and the silicon oxide layer, the third insulating layer is positioned between the polysilicon layer and the first insulating layer and the oxide transistor including a laminated oxide semiconductor layer, a second insulating layer and a fourth insulating layer, the fourth insulating layer over the oxide semiconductor layer, the second insulating layer excluding the silicon nitride layer, the second insulating layer is the same layer as the silicon oxide layer in the first insulating layer.

To solve the technical problems, another technical proposal of this invention is to provide an array substrate including a base substrate and a low temperature polysilicon transistor and an oxide transistor positioned on the base substrate, the base substrate is provided with a display region and a non-display region located around the display region, the low temperature polysilicon transistor is positioned in a non-display region, and the oxide transistor is positioned in a display region; the low temperature polysilicon transistor including a laminated polysilicon layer and a first insulating layer, the first insulating layer including silicon layer and a silicon nitride layer, wherein the silicon nitride layer is positioned between the polysilicon layer and the silicon oxide layer; the oxide transistor includes a laminated oxide semiconductor layer and a second insulating layer, and the second insulating layer is free of a silicon nitride layer.

To solve the technical problems, another technical proposal of this invention is to provide a method for manufacturing an array substrate, including: forming a low temperature polysilicon transistor and an oxide transistor on a base substrate respectively;the base substrate is provided with a display region and a non-display region located around the display region, the low temperature polysilicon transistor is positioned in a non-display region, and the oxide transistor is positioned in a display region; forming the low temperature polysilicon transistor on the base substrate includes: sequentially forming a polysilicon layer on the base substrate and a first insulating layer , the first insulating layer includes a silicon oxide layer and a silicon nitride layer, wherein the silicon nitride layer is close to the polysilicon layer; forming the oxide transistor on the base substrate includes: sequentially forming a second insulating layer and an oxide semiconductor layer on the base substrate, and the second insulating layer is free of the silicon nitride layer.

This invention has the following benefits: by laminating the polysilicon layer and the first insulating layer including the a silicon oxide layer and the silicon nitride layer in the low temperature polysilicon transistor, the silicon oxide and silicon nitride structure on the polysilicon layer is formed, and a large amount of hydrogen bonds are generated during the formation of the silicon nitride layer, so that the polysilicon layer is sufficiently repaired in the hydrogenation process, the leakage problem of the low temperature polysilicon transistor is effectively reduced, and at the same time, the oxide semiconductor layer and the second insulating layer are laminated in the oxide transistor, and the second insulating layer is free of the silicon nitride layer, so that the oxide semiconductor layer is not affected by the hydrogen bonds, thereby the reliability of the oxide transistor is improved.

### BRIEF DESCRIPTION OF THE DRAWINGS

FIG. 1 is a schematic view of an embodiment of an array substrate according to this invention;

FIG. 2 is a schematic structural view of another embodiment of the array substrate of this invention;

FIG. 3 is a flow chart of an embodiment of the array substrate manufacturing method of this invention;

FIG. 4 is a flow chart of step S11 in FIG. 3;

FIG. 5 is a schematic structural view of an embodiment of the array substrate in FIG. 4;

FIG. 6 is a flow chart of step S12 in FIG. 3;

FIG. 7 is a schematic structural view of an embodiment of the array substrate in FIG. 6;

FIG. 8 is a flow chart of another embodiment of the array substrate manufacturing method of this invention;

FIG. 9 is a schematic structural view of an embodiment of the array substrate in FIG. 8;

FIG. 10 is a schematic structural view of a display device according to this invention.

### DETAILED DESCRIPTION OF EMBODIMENTS

This invention will now be described in detail with reference to the accompanying drawings and specific embodiments.

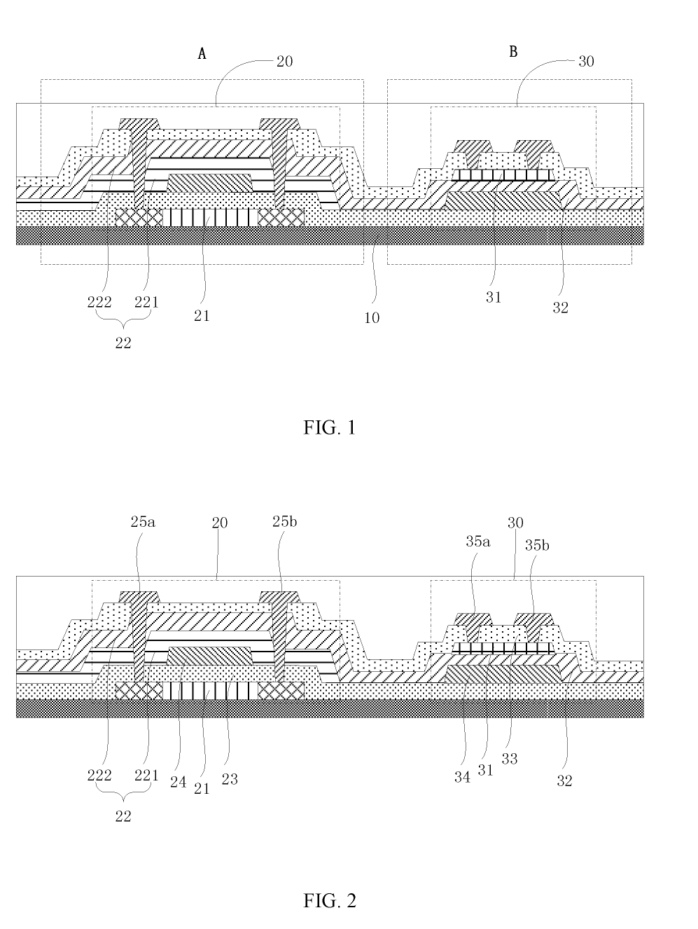

Referring to FIG. 1, FIG. 1 is a schematic view of an embodiment of an array substrate according to this invention, the array substrate includes: a base substrate 10 and a low temperature polysilicon transistor 20 and an oxide transistor 30 positioned on the base substrate 10, the base substrate is provided with a display region B and a non-display region A positioned around the display region B, the low temperature polysilicon transistor 20 is positioned in the non-display region A, and the oxide transistor 30 is positioned in the display region B. The low temperature polysilicon transistor 20 includes a laminated polysilicon layer 21 and a first insulating layer 22, the first insulating layer 22 includes a silicon oxide layer 222 and a silicon nitride layer 221, the silicon nitride layer is positioned between the polysilicon layer and the silicon oxide layer. The oxide transistor 30 includes a laminated oxide semiconductor layer 31 and a second insulating layer 32, and the second insulating layer 32 is free of the silicon nitride layer.

In the present embodiment, a low temperature polysilicon (LTPS) is combined with an oxide thin film transistor (Oxide TFT), which are manufactured in the same device, and a low temperature polysilicon transistor 20 and the oxide transistor 30 are formed on the base substrate 10. The base substrate 10 may be a glass substrate or a flexible substrate, and in some applications, the base substrate 10 may be a silicon dioxide substrate, or a polyvinyl chloride (PV), a fusible polytetrafluoroethylene (PFA), Polyethylene terephthalate (PET) substrates, and the like. The polysilicon layer 21 is positioned on the base substrate 10 and may be a semiconductor layer of a polycrystalline silicon material or a polycrystalline silicon material converted from an amorphous silicon material by solid phase crystallization (SPC) and a heat treatment process. The first insulating layer 22 may consist of a single layer of silicon nitride (SiNx) or a plurality of silicon nitride/silicon oxide (SiO₂/SiNx) layers. In the present embodiment, the first insulating layer 22 may further include a silicon oxide layer 222 and a silicon nitride layer 221, the silicon nitride layer 221 is adjacent to the polysilicon layer 21, and during the formation of the silicon nitride layer 221, a large amount of hydrogen bonds (H) are generated while silicon nitride (SiNx) is generated due to adding a large amount of NH3. The oxide semiconductor layer 31 may be at least one of indium oxide, zinc oxide, tin oxide, gallium oxide, and the like, and the second insulating layer 32 may be composed of silicon oxide (SiO₂).

By the method, a structure of silicon oxide and silicon nitride is formed on the polysilicon layer, and a large amount of hydrogen bonds are generated during the formation of the silicon nitride layer, so that the polysilicon layer is sufficiently repaired during the hydrogenation process, the leaking problem of low temperature polysilicon transistors is reduced effectively, and a silicon oxide layer is free of silicon nitride is formed in the vicinity of the oxide semiconductor layer, so that the oxide semiconductor layer is not affected by the hydrogen bonds, thereby the reliability of the oxide transistor is improved.

Further, the second insulating layer 32 may be in the same layer as the silicon oxide layer 222 of the first insulating layer 22, and finally, a structure of silicon oxide and silicon nitride is formed on the polysilicon layer by film-forming twice, and only the silicon oxide structure is near the oxide semiconductor layer.

Referring as FIG. 2, FIG. 2 is a schematic structural view of another embodiment of the array substrate of this invention. As shown in FIG. 2, the array substrate further includes a third insulating layer 23 and a fourth insulating layer 33. The third insulating layer 23 is positioned between the polysilicon layer 21 and the first insulating layer 22. And the fourth insulating layer 33 is positioned on the oxide semiconductor layer 31.

As shown in FIG. 2, the low temperature polysilicon transistor 20, distinguished by a dotted line, further includes a first gate electrode 24, a first source 25a, and a first drain electrode 25b. The first gate electrode 24 is adjacent to the polysilicon layer 21 and is positioned between the third insulating layer 23 and the first insulating layer 22. The first source electrode 25a and the first drain electrode 25b are positioned on the fourth insulating layer 33. Further, portions of the first source electrode 25a and the first drain electrode 25b are electrically connected by passing through the first contact and the second holes provided in the fourth insulating layer 33, the second insulating layer 32, the first insulating layer 22, and the third insulating layer 23, respectively, and form the low temperature polysilicon transistor of a top gate structure with the first gate electrode 24.

As shown in FIG. 2, the oxide transistor 30, distinguished by a dotted line, further includes a second gate electrode 34, a second source 35a, and a second drain electrode 35b. The second gate electrode 34 is adjacent to the oxide semiconductor layer 31 and is positioned between the third insulating layer 23 and the second insulating layer 32. The second source electrode 35a and the second drain electrode 35b are positioned on the fourth insulating layer 33. Further, portions of the second source electrode 35a and the second drain electrode 35b are electrically connected to the oxide semiconductor layer 31 through the third contact hole and the fourth contact hole provided in the fourth insulating layer 33, respectively, and form a bottom gate oxide transistor with the second gate electrode 34.

By the method, the adoption of automatic adjustment of the top gate structure to form low temperature polysilicon transistor and the adoption of the bottom gate structure to form oxide transistors can reduce the number of the mask.

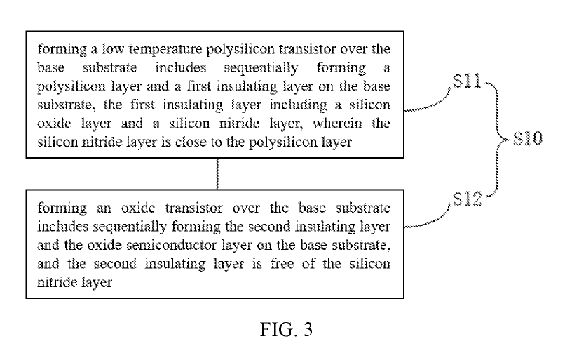

Referring to FIG. 3, FIG. 3 is a flow schematic diagram of an embodiment of the array substrate manufacturing method of this invention. The method of manufacturing the array substrate includes the following steps of:

S10: forming a low temperature polysilicon transistor and a oxide transistor on the base substrate,respectively; wherein the base substrate is provided with a display region and a non-display region positioned around the display region, the low temperature polysilicon transistor is positioned in the non-display region, the oxide transistor is positioned within the display region;

The base substrate may be a transparent material, specifically a transparent organic material having oxygen- and water-barrier properties or glass. Glass substrate and silicon dioxide substrate are commonly used, and polyvinyl chloride (PV), fusible polytetrafluoroethylene (PFA), and polyethylene terephthalate (PET) substrates may be adopted in some applications. In other embodiments, a buffer layer may be deposited on the base substrate to a certain thickness before forming the low temperature polysilicon transistor and the oxide transistor. The deposited material may be a single layer or a multilayer of SiO₂/SiNx for increasing the degree of adhesion between the polysilicon layer to be formed and the substrate, thereby reducing the heat transfer effect.

As shown in FIG. 3, step S10 includes the following sub-steps of:

S11: forming a low temperature polysilicon transistor over the base substrate includes sequentially forming a polysilicon layer and a first insulating layer on the base substrate, the first insulating layer including a silicon oxide layer and a silicon nitride layer, wherein the silicon nitride layer is close to the polysilicon layer.

S12: forming an oxide transistor over the base substrate includes sequentially forming the second insulating layer and the oxide semiconductor layer on the base substrate, and the second insulating layer is free of the silicon nitride layer.

In the present embodiment, the first insulating layer may be composed of a single layer of silicon nitride (SiNx) or a multilayer of silicon nitride/silicon oxide (SiO₂/SiNx). Further, the first insulating layer may include a silicon oxide layer and a silicon nitride layer wherein the silicon nitride layer is close to the polysilicon layer;and during the formation of the silicon nitride layer, a large amount of hydrogen bonds (H) are generated while silicon nitride (SiNx) is generated due to adding a large amount of NH3, to provide the hydrogen needed for hydrogenation of polysilicon. And the second insulating layer is composed of silicon oxide (SiO₂) to prevent the oxide transistor from being affected by H.

By the method, a structure of silicon oxide and silicon nitride is formed on the polysilicon layer, and a large amount of hydrogen bonds are generated during the formation of the silicon nitride layer, so that the polysilicon layer is sufficiently repaired during the hydrogenation process, the leaking problem of low temperature polysilicon transistors is reduced effectively, and a silicon oxide layer is free of silicon nitride is formed on the oxide semiconductor layer, so that the oxide semiconductor layer is not affected by the hydrogen bonds, thereby the reliability of the oxide transistor is improved.

Further, silicon oxide is deposited on the base substrate to form the second insulating layer, and the second insulating layer is in the same layer as the silicon oxide layer in the first insulating layer. In the specific implementation process, silicon nitride is deposited on the polysilicon layer to form the first insulating layer, and the silicon oxide is further deposited on the first insulating layer to form the second insulating layer;finally, the structure of silicon oxide and silicon nitride is formed on the polysilicon layer by film-forming twice, and only the silicon oxide structure is near the oxide semiconductor layer.

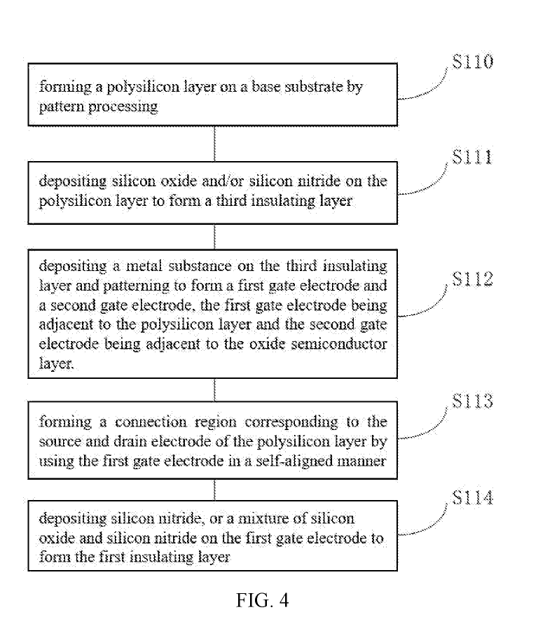

As shown in FIG. 4, FIG. 4 is a flow chart of step S11 in FIG. 3, and step S11 further includes the following sub-steps of:

S110: forming a polysilicon layer on a base substrate by pattern processing.

S111: depositing silicon oxide and/or silicon nitride on the polysilicon layer to form a third insulating layer.

S112: depositing a metal substance on the third insulating layer and patterning to form a first gate electrode and a second gate electrode, the first gate electrode being adjacent to the polysilicon layer and the second gate electrode being adjacent to the oxide semiconductor layer.

S113: forming a connection region corresponding to the source and drain electrode of the polysilicon layer by using the first gate electrode in a self-aligned manner.

S114: depositing silicon nitride, or a mixture of silicon oxide and silicon nitride on the first gate electrode to form the first insulating layer.

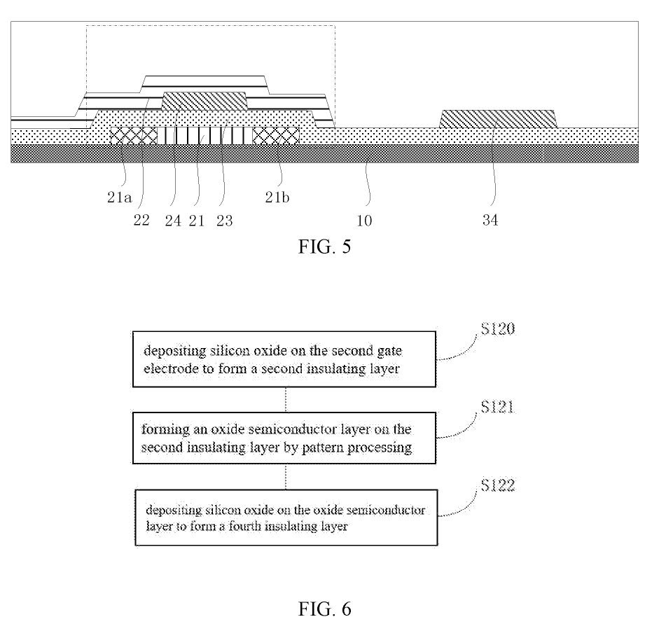

Referring to FIG. 5, the sub-step S110 includes the steps of: depositing a layer of polysilicon on the base substrate 10 and patterning the polysilicon layer 21 to form a low temperature polysilicon layer, wherein the patterning process may include photoresist coating, exposure, development, etching, photoresist peeling, and other processes. In other embodiments, an amorphous silicon layer (a-Si) may also be deposited, and the amorphous silicon layer (a-Si) may be converted to a polysilicon layer by using Solid Phase Crystallization (SPC) and then form the low temperature polysilicon layer, which is not limited thereto.

The sub-step S111 specifically includes: continuously depositing a single layer of the silicon oxide (SiO₂) film layer or the silicon nitride (SiNx) film layer,or a laminated layer of silicon oxide (SiO₂) and silicon nitride (SiNx) after the polysilicon layer 21 is formed and is subjected to pattern processing, to form a third insulating layer 23 overlying the polysilicon layer 21 and the substrate 20 for isolating the polysilicon layer 21 from the other metal layers to avoid short circuits.

In other embodiments, a buffer layer (not shown) of a certain thickness may be deposited on the base substrate 10 prior to forming the polysilicon layer 21 and the third insulating layer 23. The deposited material may be a single layer or a multilayer of SiO₂/SiNx for increasing the degree of adhesion between the polysilicon layer to be formed and the substrate, thereby reducing the heat transfer effect.

The sub-step S112 specifically includes: depositing a layer of metal on the third insulating layer 23, forming a first gate electrode 24 and a second gate electrode 34 having predetermined patterns by photoresist coating, exposure, development, etching, photoresist peeling and the like. The first gate electrode 24 is adjacent to the polysilicon layer 21 and the second gate electrode 34 is adjacent to the oxide semiconductor layer. The material of the first gate electrode 24 and the second gate electrode 34 may be any combination of metals such as aluminum (A1), molybdenum (Mo), chromium (Cr), copper (Cu), and titanium (Ti).

The sub-step S113 specifically includes: forming the source and drain connection regions 21a and 21b of the polysilicon layer 21 by using the first gate electrode 24 in the self-aligned manner, and using the connection regions for automatically electrically connecting to the corresponding source and the drain electrodes.

Alternatively, step S113 may be performed after S111 and S112, or may be performed before S111 and S112, and is not limited thereto. To avoid the operation of dividing the connection regions corresponding to the source electrode and the drain electrode to other operations, S113 may be selected after S111 and S112.

The sub-step S114 specifically includes: depositing silicon nitride, or a mixture of silicon oxide and silicon nitride on the first gate electrode 24 to form the first insulating layer 22 and performing a patterning process. The first insulating layer 22 only covers the first gate electrode 24 and portions of the third insulating layer 23 corresponding to the polysilicon layer 21. During the formation of the silicon nitride layer, a large amount of hydrogen bonds (H) are generated while silicon nitride (SiNx) is generated due to adding a large amount of NH3, to provide hydrogen needed for hydrogenation of polysilicon.

In other application, the first gate electrode 24 and the second gate electrode 34 may also be formed by other forming methods such as spraying, and are not limited thereto.

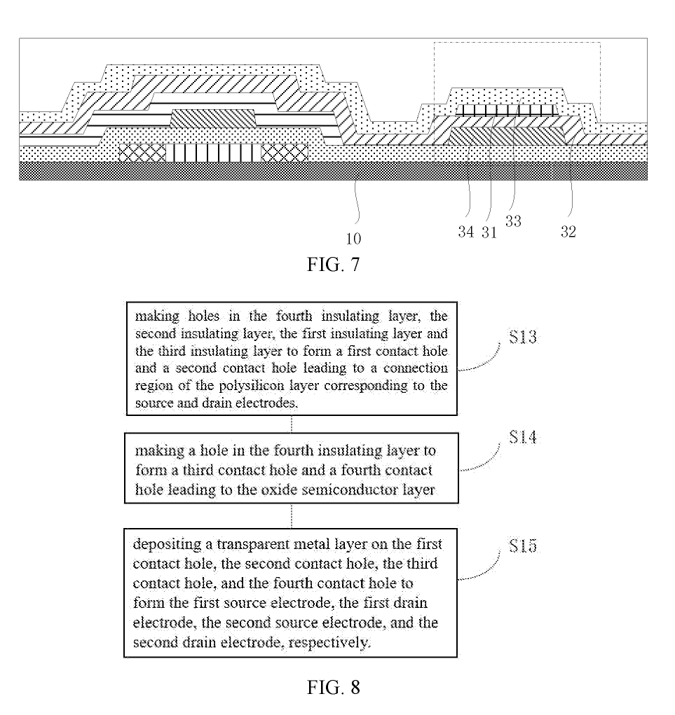

As shown in FIG. 6 and FIG. 7, FIG. 6 is a flow chart of step S12 in FIG. 3, and step S12 further includes the following sub-steps of:

S120: depositing silicon oxide on the second gate electrode to form a second insulating layer.

S121: forming an oxide semiconductor layer on the second insulating layer by pattern processing.

S122: depositing silicon oxide on the oxide semiconductor layer to form a fourth insulating layer.

Referring to FIG. 7, the sub-step S120 specifically includes: depositing silicon oxide on the second gate electrode 34 to form the second insulating layer 32. The second insulating layer 32 is covered on the second gate electrode 34, the third insulating layer, and the first insulating layer, for isolating the second gate electrode 34 from the other metal layers and avoiding short circuits. In other application, the second insulating layer 32 may be in the same layer as the silicon oxide layer of the first insulating layer.

The sub-step S121 specifically includes: forming the oxide semiconductor layer 31 on the second insulating layer 32 by pattern processing. In the present embodiment, the oxide used in the oxide semiconductor layer 31 is an oxide semiconductor material such as indium gallium zinc oxide (IGZO) or indium tin zinc oxide (ITZO).

The sub-step S122 specifically includes: depositing an insulating material such as silicon oxide or resin on the oxide semiconductor layer 31 to form the fourth insulating layer 33, the fourth insulating layer 33 is covered on the oxide semiconductor layer 31 and the second insulating layer 32, for isolating the oxide semiconductor layer 31 from other metal layers to avoid short circuits.

As shown in FIG. 8, FIG. 8 is a flow chart of another embodiment of a method for manufacturing an array substrate of this invention. The method of manufacturing the array substrate further includes the following steps of:

S13: making holes in the fourth insulating layer, the second insulating layer, the first insulating layer and the third insulating layer to form a first contact hole and a second contact hole leading to a connection region of the polysilicon layer corresponding to the source and drain electrodes.

S14: making a hole in the fourth insulating layer to form a third contact hole and a fourth contact hole leading to the oxide semiconductor layer.

S15: depositing a transparent metal layer on the first contact hole, the second contact hole, the third contact hole, and the fourth contact hole to form the first source electrode, the first drain electrode, the second source electrode, and the second drain electrode, respectively.

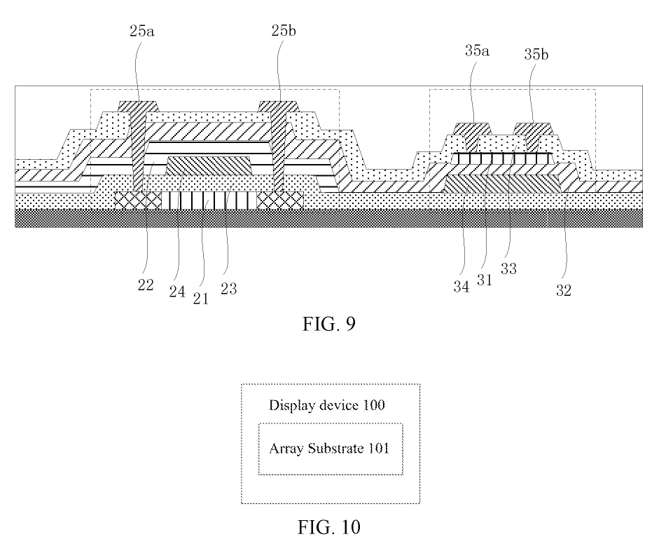

As shown in FIG. 9, holes are made in the fourth insulating layer 33, the second insulating layer 32, the first insulating layer 22, and the third insulating layer 23 to form the first contact hole and the second contact hole leading to a connection region of polysilicon layer 21 corresponding to the source and drain electrodes, and depositing a transparent metal to the first contact hole and the second contact hole such that a portion of the metal is electrically connected to the doping region of the polysilicon layer 21 in a self-aligned manner through contact holes to form a first source electrode 25a and a first drain electrode 25b. The first source electrode 25a, the first drain electrode 25b, and the first gate electrode 24 form a low temperature polysilicon transistor having a top gate structure.

Similarly, a third contact hole and a fourth contact hole leading to the oxide semiconductor layer 31 are formed in the fourth insulating layer 33 to form a transparent metal to the third contact hole and the fourth contact hole so that a part of the metal passes through The contact hole is electrically connected to the oxide semiconductor layer 31 to form the second source electrode 35a and the second drain electrode 35b. The second source electrode 35a, the second drain electrode 35b, and the second gate electrode 34 form an oxide transistor having a bottom gate structure. In the specific implementation, the first source electrode 25a, the first drain electrode 25b, the second source electrode 35a, and the second drain electrode 35b may be simultaneously formed by a patterning process, which may be aluminum (Al), molybdenum (Mo), chromium (Cr), copper (Cu), titanium (Ti) and the like.

By the method, the adoption of automatic adjustment of the top gate structure to form low temperature polysilicon transistor and the adoption of the bottom gate structure to form oxide transistors can reduce the number of the mask.

Further, a PV layer, a PLN layer, an OLED layer, a cathode, etc., are successively formed on the first source electrode 25a, the first drain electrode 25b, the second source electrode 35a, and the second drain electrode 35b to obtain a complete TFT substrate.

The display device 100 further includes an array substrate 101, as shown in FIG. 10, the display device 100 includes an array substrate 101 of any structures, or an array substrate 101 manufactured by any one of the methods, the specific methods are as the embodiments, the method may be used to manufacture the array substrate shown in FIG. 1 or 2 and will not be described here. Further, the display device may be an active matrix organic light emitting diode (AMOLED) or a TFT LCD display device. The array substrate includes a base substrate and a low temperature polysilicon transistor and an oxide transistor positioned on the base substrate, the substrate is provided with a display region and a non-display region positioned around the display region, the low temperature polysilicon transistor is positioned in the non-display region, the oxide transistor is positioned in the display region. The low temperature polysilicon transistor includes a laminated polysilicon layer and a first insulating layer, the first insulating layer includes a silicon oxide layer and a silicon nitride layer, wherein the silicon nitride layer is close to the polysilicon layer. The oxide transistor includes the laminated oxide semiconductor layer and the second insulating layer, and the second insulating layer is free of a silicon nitride layer. During the process of forming the silicon nitride layer, due to the addition of a large amount of ammonia, a lot of hydrogen bonds are generated while silicon nitride is generated, making the polysilicon layer in the hydrogenation process is sufficiently repaired during the hydrogenation process, the leaking problem of low temperature polysilicon transistors is reduced effectively, and a silicon oxide layer is free of silicon nitride is formed in the vicinity of the oxide semiconductor layer, so that the oxide semiconductor layer is not affected by the hydrogen bonds, thereby the reliability of the oxide transistor is improved.

Above are only embodiments of this invention is not patented and therefore limit the scope of this invention, the use of any content of the present specification and drawings made equivalent or equivalent structural transformation process, either directly or indirectly related to the use of other technologies areas are included in the same way the scope of the patent protection of this invention.

What is claimed is:

1. A display device, wherein the display device comprises an array substrate,the array substrate comprises a base substrate and a low temperature polysilicon transistor and an oxide transistor positioned on the base substrate, the base substrate is provided with a display region and a non-display region located around the display region, the low temperature polysilicon transistor being positioned in the non-display region, the oxide transistor being positioned in the display region;
the low temperature polysilicon transistor comprises a laminated polysilicon layer, a first insulating layer, and a third insulating layer, the first insulating layer comprising a silicon oxide layer and a silicon nitride layer,
wherein the silicon nitride layer is positioned between the polysilicon layer and the silicon oxide layer, the third insulating layer being positioned between the polysilicon layer and the first insulating layer;
the oxide transistor comprises a laminated oxide semiconductor layer, a second insulating layer, and a fourth insulating layer, the fourth insulating layer being positioned on the oxide semiconductor layer, and the second insulating layer is free of silicon nitride layer, the second insulating layer being a same layer as the silicon oxide layer in the first insulating layer.

2. The display device according to claim 1, wherein the low temperature polysilicon transistor further comprises:
a first gate electrode, adjacent to the polysilicon layer, positioned between the third insulating layer and the first insulating layer;
a first source electrode and a first drain electrode, positioned on the fourth insulating layer;
wherein portions of the first source electrode and the first drain electrode are electrically connected to the polysilicon layer by passing respectively through a first contact hole and a second contact hole disposed in the fourth insulating layer, the second insulating layer, the first insulating layer, and the third insulating layer, and form a low temperature polysilicon transistor of a top gate structure with the first gate electrode;
the oxide transistor further comprising:
a second gate electrode, adjacent to the oxide semiconductor layer, is positioned between the third insulating layer and the second insulating layer;
a second source electrode and a second drain electrode, positioned on the fourth insulating layer;
wherein portions of the second source electrode and the second drain electrode are electrically connected to the oxide semiconductor layer by passing respectively through a third contact hole and a fourth contact hole disposed in the fourth insulating layer, and form an oxide transistor of a bottom gate structure with the second gate electrode.

3. The display device according to claim 1, wherein the array substrate comprises a manufacturing method as follows:
the low temperature polysilicon transistor and the oxide transistor are respectively formed on the base substrate, and the base substrate is provided with the display region and the non-display region located around the display region, the low temperature polysilicon transistor being positioned in the non-display region, the oxide transistor being positioned in the display region;
the low temperature polysilicon transistor formed on the base substrate comprises:
forming the polysilicon layer and the first insulating layer on the base substrate sequentially, the first insulating layer comprising the silicon oxide layer and the silicon nitride layer,
wherein the silicon nitride layer is close to the polysilicon layer;
the oxide transistor formed on the base substrate comprises: forming the second insulating layer and the oxide semiconductor layer on the base substrate sequentially, and the second insulating layer is free of the silicon nitride layer.

4. The display device according to claim 3, wherein the second insulating layer and the oxide semiconductor layer are sequentially formed on the base substrate, comprising:
depositing silicon oxide on the base substrate to form the second insulating layer, the second insulating layer being the same layer as the silicon oxide layer in the first insulating layer.

5. The display device according to claim 3, wherein the polysilicon layer and the first insulating layer are sequentially formed on the base substrate, comprising:
forming the polysilicon layer on the base substrate by pattern processing;
depositing silicon oxide and/or silicon nitride on the polysilicon layer to form the third insulating layer;
depositing a metal substance on the third insulating layer and forming a first gate electrode and a second gate electrode by pattern processing, the first gate electrode being adjacent to the polysilicon layer, the second gate electrode being adjacent to the oxide semiconductor layer;
using the first gate electrode to form a connection region of the polysilicon layer corresponding to source and drain electrodes in a self-aligned manner;
depositing silicon nitride or a mixture of silicon oxide and silicon nitride on the first gate electrode to form the first insulating layer;
the second insulating layer and the oxide semiconductor layer sequentially being formed on the base substrate, comprising:
depositing silicon oxide on the second gate electrode to form the second insulating layer;
forming the oxide semiconductor layer on the second insulating layer by pattern processing;
depositing silicon oxide on the oxide semiconductor layer to form the fourth insulating layer.

6. The display device according to claim 5, wherein
making holes in the fourth insulating layer, the second insulating layer, the first insulating layer, and the third insulating layer to form a first contact hole and a second contact hole leading to a connection region of the polysilicon layer corresponding to the source and drain electrodes;
making holes in the fourth insulating layer to form a third contact hole and a fourth contact hole leading to the oxide semiconductor layer;
depositing a transparent metal layer on the first contact hole, the second contact hole, the third contact hole, and the fourth contact hole to form a first source electrode, a first drain electrode, a second source electrode, and a second drain electrode.

7. The display device according to claim 1, wherein the display device is an active matrix organic light emitting diode (AMOLED) or a thin film transistor liquid crystal display (TFT LCD) display device.

8. An array substrate, wherein the array substrate comprises a base substrate and a low temperature polysilicon transistor and an oxide transistor positioned on the base substrate, the base substrate being provided with a display region and a non-display region located around the display region, the low temperature polysilicon transistor being positioned in the non-display region, the oxide transistor being positioned in the display region;
the low temperature polysilicon transistor comprises a laminated polysilicon layer and a first insulating layer, the first insulating layer comprises a silicon oxide layer and a silicon nitride layer,
wherein the silicon nitride layer is positioned between the polysilicon layer and the silicon oxide layer;
the oxide transistor comprises a laminated oxide semiconductor layer and a second insulating layer, the second insulating layer being free of a silicon nitride layer.

9. The array substrate according to claim 8, wherein the second insulating layer is the same layer as the silicon oxide layer in the first insulating layer.

10. The array substrate according to claim 8, wherein the array substrate further comprises:
a third insulating layer, positioned between the polysilicon layer and the first insulating layer;
a fourth insulating layer, positioned on the oxide semiconductor layer.

11. The array substrate according to claim 10, wherein the low temperature polysilicon transistor further comprises:
a first gate electrode, adjacent to the polysilicon layer, positioned between the third insulating layer and the first insulating layer;
a first source electrode and a first drain electrode, positioned on the fourth insulating layer;
wherein portions of the first source electrode and the first drain electrode are electrically connected to the polysilicon layer by passing respectively through a first contact hole and a second contact hole disposed in the fourth insulating layer, the second insulating layer, the first insulating layer, and the third insulating layer, and form the low temperature polysilicon transistor of a top gate structure with the first gate electrode;
the oxide transistor further comprises:
a second gate electrode, adjacent to the oxide semiconductor layer, positioned between the third insulating layer and the second insulating layer; and
a second source electrode and a second drain electrode, positioned on the fourth insulating layer;
wherein portions of the second source electrode and the second drain electrode are electrically connected to the oxide semiconductor layer by passing respectively through a third contact hole and a fourth contact hole disposed in the fourth insulating layer, and form an oxide transistor of the bottom gate structure with the second gate electrode.

12. A method of manufacturing an array substrate, comprising:
a low temperature polysilicon transistor and an oxide transistor are respectively formed on a base substrate, the base substrate is provided with a display region and a non-display region located around the display region, the low temperature polysilicon transistor being positioned in the non-display region, the oxide transistor being positioned within the display region;
the low temperature polysilicon transistor formed on the base substrate comprises:
forming a polysilicon layer and a first insulating layer on the base substrate sequentially, the first insulating layer comprising a silicon oxide layer and a silicon nitride layer,
wherein the silicon nitride layer is close to the polysilicon layer;
the oxide transistor formed on the base substrate comprises: forming a second insulating layer and an oxide semiconductor layer on the base substrate sequentially, the second insulating layer being free of a silicon nitride layer.

13. The display device according to claim 12, wherein the second insulating layer and the oxide semiconductor layer sequentially formed on the base substrate comprise:
depositing silicon oxide on the base substrate to form the second insulating layer, the second insulating layer being the same layer as the silicon oxide layer in the first insulating layer.

14. The method according to claim 12, wherein the polysilicon layer and the first insulating layer sequentially formed on the base substrate comprise:
forming a polysilicon layer on the base substrate by pattern processing;
depositing silicon oxide and/or silicon nitride on the polysilicon layer to form a third insulating layer;
depositing a metal substance on the third insulating layer and forming a first gate electrode and a second gate electrode by pattern processing, the first gate electrode being adjacent to the polysilicon layer, the second gate electrode being adjacent to the oxide semiconductor layer;
using the first gate electrode to form a connection region of the polysilicon layer corresponding to the source and drain electrodes in a self-aligned manner;
depositing silicon nitride or a mixture of silicon oxide and silicon nitride on the first gate electrode to form the first insulating layer;
the second insulating layer and the oxide semiconductor layer sequentially formed on the base substrate comprise:
depositing silicon oxide on the second gate electrode to form the second insulating layer;
forming the oxide semiconductor layer on the second insulating layer by pattern processing;
depositing silicon oxide on the oxide semiconductor layer to form a fourth insulating layer.

15. The method according to claim 14, wherein the method future comprises:
making holes in the fourth insulating layer, the second insulating layer, the first insulating layer, and the third insulating layer to form a first contact hole and a second contact hole leading to the connection region of the polysilicon layer corresponding to the source and drain electrodes;
making holes in the fourth insulating layer to form a third contact hole and a fourth contact hole leading to the oxide semiconductor layer;
depositing a transparent metal layer on the first contact hole, the second contact hole, the third contact hole, and the fourth contact hole to form a first source electrode, a first drain electrode, a second source electrode, and a second drain electrode.
